(19) United States
(12) Patent Application Publication
(10) Pub. No.: US 2012/0024233 A1
(43) Pub. Date: Feb. 2, 2012

(54) Conveyor Assembly with Releasable Drive Coupling

(75) Inventor: Max William Reed, Niwot, CO (US)

(73) Assignee: PRIMESTAR SOLAR, INC., Arvada, CO (US)

(21) Appl. No.: 12/975,493

(22) Filed: Dec. 22, 2010

(51) Int. Cl. C23C 16/00

(52) U.S. Cl. 118/729

(57) ABSTRACT

A module for a deposition system includes a drive unit mounted on an exterior wall of the module. The drive unit has a drive shaft that extends into the module and engages a conveyor operably disposed within the module for driving the conveyor in a conveying path. A releasable drive coupling is configured between the drive unit and a drive member of the conveyor. The drive coupling has a first end that releasably engages with the drive shaft and a second end that releasably engages the conveyor drive member. The drive coupling includes a torque member, and may also include at least one thermal shield spaced concentrically around the torque member and extending axially between the first and second ends.

### FIELD OF THE INVENTION

The present subject matter relates generally to the field of conveyors, and more particularly to an improved conveyor drive system for use in thin film deposition systems wherein a thin film layer, such as a semiconductor material layer, is deposited on a substrate conveyed through the module.

### BACKGROUND OF THE INVENTION

Thin film photovoltaic (PV) modules (also referred to as “solar panels”) are gaining wide acceptance and interest in the industry, particularly modules based on cadmium telluride (CdTe) paired with cadmium sulfide (CdS) as the photo-reactive components. Solar energy systems using CdTe PV modules are generally recognized as the most cost efficient of the commercially available systems in terms of cost per watt of power generated. However, the advantages of CdTe not withstanding, sustainable commercial exploitation and acceptance of solar power as a supplemental or primary source of industrial or residential power depends on the ability to produce efficient PV modules on a large scale and in a cost effective manner.

The ability to process relatively large substrates on an economically sensible commercial scale is thus a crucial consideration and, in this regard, down time of the deposition modules for maintenance and repair should be minimized. Maintenance on the module conveyor typically requires disconnecting the drives from the conveyors, which can be a tedious and timely exercise. Subsequent alignment of the drives with the conveyor components can also be problematic. Diagnosing problems with the module drives while the units are under operating temperature and vacuum conditions can also be difficult. In addition, the life of the conveyor drives can be significantly shortened by transmission of the tremendous heat generated in the deposition module to the externally mounted drive components, which also results in down time of the system to replace the components.

Accordingly, there exists an ongoing need for deposition modules with improved drive systems that reduce maintenance/repair down time, as well as address other disadvantages noted above.

### BRIEF DESCRIPTION OF THE INVENTION

Aspects and advantages of the invention will be set forth in part in the following description, or may be obvious from the description, or may be learned through practice of the invention.

In accordance with aspects of the invention, a module is provided for a system wherein a sublimated source material is deposited as a thin film on a substrate conveyed through one or more of the modules. In a particular embodiment, the module is a vapor deposition module configured for deposition of a thin film of photo-reactive material on a PV substrate. The module may also be one or more of the modules in the system that conveys the substrate to and from the deposition module. The module includes a drive unit mounted on an exterior wall of the module, with the drive unit having a drive shaft that extends into the module. A conveyor is operably disposed within the module and is configured to be driven in a conveying path by the drive unit. For example, in a particular embodiment, the conveyor is driven in an endless loop path between opposite sprockets within the module. A releasable drive coupling is configured between the drive unit and a drive member of the conveyor, which may be a sprocket shaft. The drive coupling has a first end that releasably engages the drive shaft and a second end that releasably engages the conveyor drive member. The drive coupling includes a torque member and at least one thermal shield spaced concentrically around the torque and extending axially between the first and second ends.

In a particular embodiment, the torque member includes an innermost torque transmission tube and a plurality of the concentric thermal shields disposed around the torque transmission tube.

The drive coupling may be axially movable along at least one of the drive shaft or conveyor drive member for disconnecting and removal of the drive coupling. A releasable locking device may be provided for axially fixing the drive coupling relative to the drive shaft and conveyor drive member.

To accommodate some degree of misalignment between the drive unit and conveyor drive member, a particular embodiment may include a partially rounded interface between the first end of the drive coupling and the drive shaft and between the second end of the drive coupling and the conveyor drive member.

In an embodiment wherein the conveyor is driven in an endless loop path between opposite sprockets, a selectively actuatable clutch may be operably configured between the drive unit and drive shaft. Another respective drive unit with associated clutch and drive coupling may be configured with a shaft on the opposite sprocket. The clutches may be operably interfaced so that the clutches cannot be simultaneously engaged. For example, the clutches may be pneumatic clutches with a controllable three-way valve disposed between an air source and the clutches, wherein the valve permits actuating airflow to only one of clutch at a time.

In still another embodiment, a deposition module is provided wherein a sublimated source material is deposited as a thin film on a substrate conveyed through said module. The module includes a conveyor operably disposed within the module to be driven in an endless loop path between opposite sprockets, with at least one of the sprockets being a drive sprocket. A drive unit is mounted on an exterior wall of the module for each of the sprockets, with each of the drive units having a drive shaft that extends into the module. A releasable drive coupling is configured between each drive unit and respective sprocket. The drive coupling includes a first end that releasably engages the drive shaft and a second end that releasably engages the drive sprocket. A selectively actuatable clutch is configured between each drive unit and respective drive shaft, with the clutches operably interfaced so that the clutches cannot be simultaneously engaged.

In a unique embodiment, the deposition module includes a conveyor housing disposed within the module, with the conveyor and sprockets configured within the conveyor housing. The conveyor housing may be removable from the module upon disconnecting the drive coupling from the drive shafts and sprockets.

Variations and modifications to the embodiments of the deposition module discussed above are within the scope and spirit of the invention and may be further described herein.

These and other features, aspects and advantages of the present invention will become better understood with reference to the following description and appended claims.

### BRIEF DESCRIPTION OF THE DRAWING

A full and enabling disclosure of the present invention, including the best mode thereof, is set forth in the specification, which makes reference to the appended drawings, in which:

FIG. 1 is a plan view of a vapor deposition system that may incorporate one or more modules in accordance with aspects of the present invention;

FIG. 2 is a perspective view of a module;

FIG. 3 is a perspective view of the conveyor assembly from the module of FIG. 2;

FIG. 4 is a more detailed perspective view of the components of the conveyor assembly of FIG. 3;

FIG. 5 is a side view of an embodiment of a drive coupling for use in a conveyor assembly;

FIG. 6 is a perspective view of the drive coupling of FIG. 5;

FIG. 7 is a cross-sectional view of the drive coupling of FIG. 6;

FIG. 8 is a perspective view of a drive shaft; and,

FIG. 9 is an assembled view of a drive coupling between a motor drive shaft and sprocket drive shaft.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment, can be used with another embodiment to yield a still further embodiment. Thus, it is intended that the present invention encompass such modifications and variations as come within the scope of the appended claims and their equivalents.

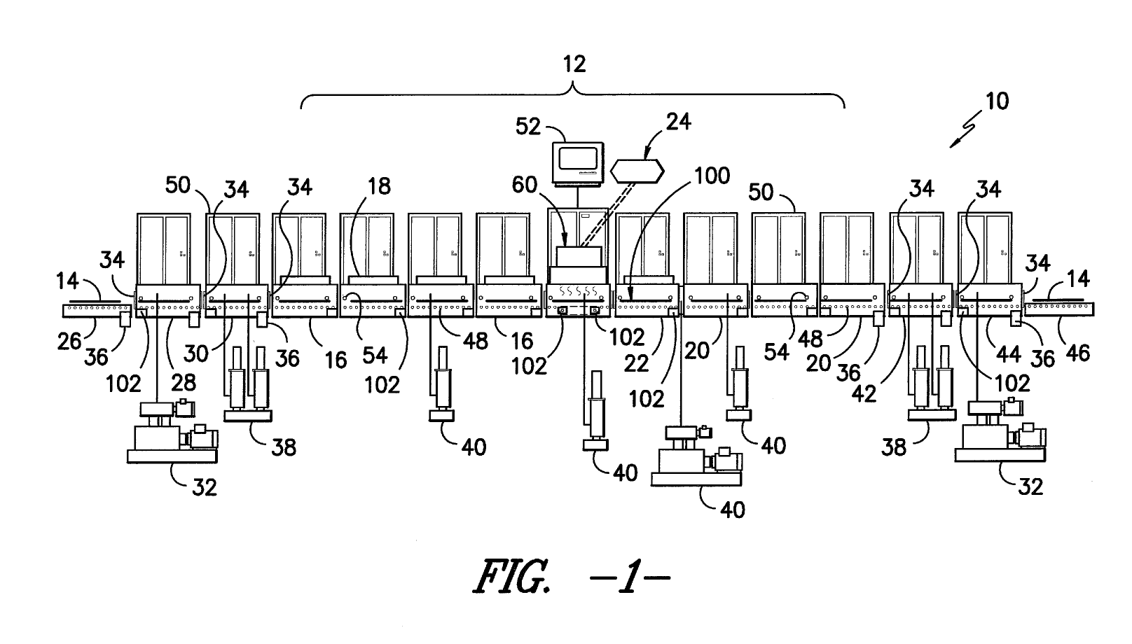

FIG. 1 illustrates an embodiment of a vapor deposition system 10 that may incorporate one or more modules 100 in accordance with aspects of the invention. The system 10 is configured for deposition of a thin film layer on a photovoltaic (PV) module substrate 14 (referred to hereafter as “substrate”). The thin film may be, for example, a film layer of cadmium telluride (CdTe). Although the invention is not limited to any particular film thickness, as mentioned, it is generally recognized in the art that a “thin” film layer on a PV module substrate is generally less than about 10 microns (μm).

For reference and an understanding of an environment in which the present modules 100 may be used, the system 10 of FIG. 1 is described below, followed by a more detailed description of a particular module 100. It should be appreciated that the modules 100 with uniquely configured conveyor drives 102 in accordance with aspects of the invention are not limited to use in the system 10 illustrated in FIG. 1, but may be incorporated into any suitable processing line configured for vapor deposition of a thin film layer onto a substrate 14.

Referring to FIG. 1, the exemplary system 10 includes a vacuum chamber 12 defined by a plurality of interconnected modules 100, one or more of which include a drive unit 102 for providing rotational drive to an internal conveyor 48. Any combination of vacuum pumps 40 may be configured with the interconnected modules to draw and maintain a vacuum effective for the deposition process within the chamber 12. Certain of the modules 100 are interconnected heater modules 16 that define a pre-heat section of the vacuum chamber 12 through which the substrates 14 are conveyed and heated to a desired temperature before being conveyed into a vapor deposition module 60. Each of the heater modules 16 may include a plurality of independently controlled heaters 18, with the heaters defining a plurality of different heat zones. A particular heat zone may include more than one heater 18. The heaters 18 may be disposed above or below the module bodies.

The vapor deposition module 60 may take on various configurations and operating principles within the scope and spirit of the invention, and is generally configured for vapor deposition of a source material, such as CdTe, as a thin film on the PV module substrates 14. In the embodiment of the system 10 illustrated in FIG. 1, the module 60 includes a casing in which the internal components are contained, including a vacuum deposition head mounted above a conveyor assembly.

The vacuum chamber 12 also includes a plurality of interconnected cool-down modules 20 within the vacuum chamber 12 downstream of the vapor deposition module 60. The cool-down modules 20 define a cool-down section within the vacuum chamber 12 in which the substrates 14 having the thin film of source material deposited thereon are allowed to cool at a controlled cool-down rate prior to the substrates 14 being removed from the system 10. Each of the modules 20 may include a forced cooling system wherein a cooling medium, such as chilled water, refrigerant, or other medium is pumped through cooling coils configured with the modules 20.

In the illustrated embodiment of system 10, at least one post-heat module 22 is located immediately downstream of the vapor deposition module 60 and before the cool-down modules 20. As the leading section of a substrate 14 is conveyed out of the vapor deposition module 60, it moves into the post-heat module 22, which maintains the temperature of the substrate 14 at essentially the same temperature as the remaining portion of the substrate 14 within the vapor deposition module 60. In this way, the leading section of the substrate 14 is not allowed to cool while the trailing section of the substrate 14 is still within the vapor deposition apparatus 60.

As diagrammatically illustrated in FIG. 1, a feed device 24 is configured with the vapor deposition module 60 to supply source material, such as granular CdTe. Preferably, the feed device 24 is configured so as to supply the source material without interrupting the continuous vapor deposition process within the module 60 or conveyance of the substrates 14 through the module 60.

Still referring to FIG. 1, the individual substrates 14 are initially placed onto a load conveyor module 26, and are subsequently moved into an entry vacuum lock station that includes a load module 28 and a buffer module 30. A “rough” (i.e., initial) vacuum pump 32 is configured with the load module 28 to draw an initial vacuum, and a “fine” (i.e., high) vacuum pump 38 is configured with the buffer module 30 to increase the vacuum in the buffer module 30 to essentially the vacuum within the vacuum chamber 12. Valves 34 (e.g., gate type slit valves or rotary-type flapper valves) are operably disposed between the load conveyor 26 and the load module 28, between the load module 28 and the buffer module 30, and between the buffer module 30 and the vacuum chamber 12. These valves 34 are sequentially actuated by a motor or other type of actuating mechanism 36 in order to introduce the substrates 14 (starting at atmospheric pressure) into the vacuum chamber 12 in a step-wise manner without affecting the vacuum within the chamber 12.

An exit vacuum lock station is configured downstream of the last cool-down module 20, and operates essentially in reverse of the entry vacuum lock station described above. For example, the exit vacuum lock station may include an exit buffer module 42 and a downstream exit lock module 44. Sequentially operated valves 34 are disposed between the buffer module 42 and the last one of the cool-down modules 20, between the buffer module 42 and the exit lock module 44, and between the exit lock module 44 and an exit conveyor module 46. A fine vacuum pump 38 is configured with the exit buffer module 42, and a rough vacuum pump 32 is configured with the exit lock module 44. The pumps 32, 38 and valves 34 are sequentially operated to move the substrates 14 out of the vacuum chamber 12 in a step-wise fashion without loss of vacuum condition within the vacuum chamber 12.

System 10 also includes a coordinated conveyor system configured to move the substrates 14 into, through, and out of the vacuum chamber 12. In the illustrated embodiment, this conveyor system includes a plurality of individually controlled conveyor assemblies 48 within each of the various modules in the system 10. Although the releasable drive coupling of the present invention is particularly suited for the conveyor assembly in the vapor deposition module 60, it should be appreciated that the drive couplings are not limited in this regard. Any combination of the respective conveyor assemblies 48 within any of the modules in system 10 may include one or more of the drive units 102 with releasable couplings 120 as discussed in greater detail below.

As described, each of the various modules and respective conveyors in the system 10 are independently controlled to perform a particular function. For such control, each of the individual modules may have an associated independent controller 50 configured therewith to control the individual functions of the respective module, including the conveyance rate of the conveyor assemblies 48 (and thus the speed of the drive units 102). The plurality of controllers 50 may, in turn, be in communication with a central system controller 52, as illustrated in FIG. 1. The central system controller 52 can monitor and control (via the independent controllers 50) the functions of any one of the modules so as to achieve an overall desired heat-up rate, deposition rate, cool-down rate, and so forth, in processing of the substrates 14 through the system 10.

Referring to FIG. 1, for independent control of the functions performed by the modules within the overall system configuration 10, including individual control of the respective drive units 102, the modules may include active-sensing viewport assemblies 54 that detect the presence of the substrates 14 as they are conveyed through the module. The viewport assemblies 54 are in communication with the respective module controller 50, which is in turn in communication with the central controller 52. The viewport assemblies 54 may be in direct communication with the central controller 52 in an alternate embodiment. In this manner, the individual respective conveyor assemblies 48 and drive units 102 may be controlled to ensure that a proper spacing between the substrates 14 is maintained and that the substrates 14 are conveyed at the desired constant conveyance rate through the vacuum chamber 12. It should be appreciated that the viewport assemblies may be used for any other control function related to the individual modules or overall system 10.

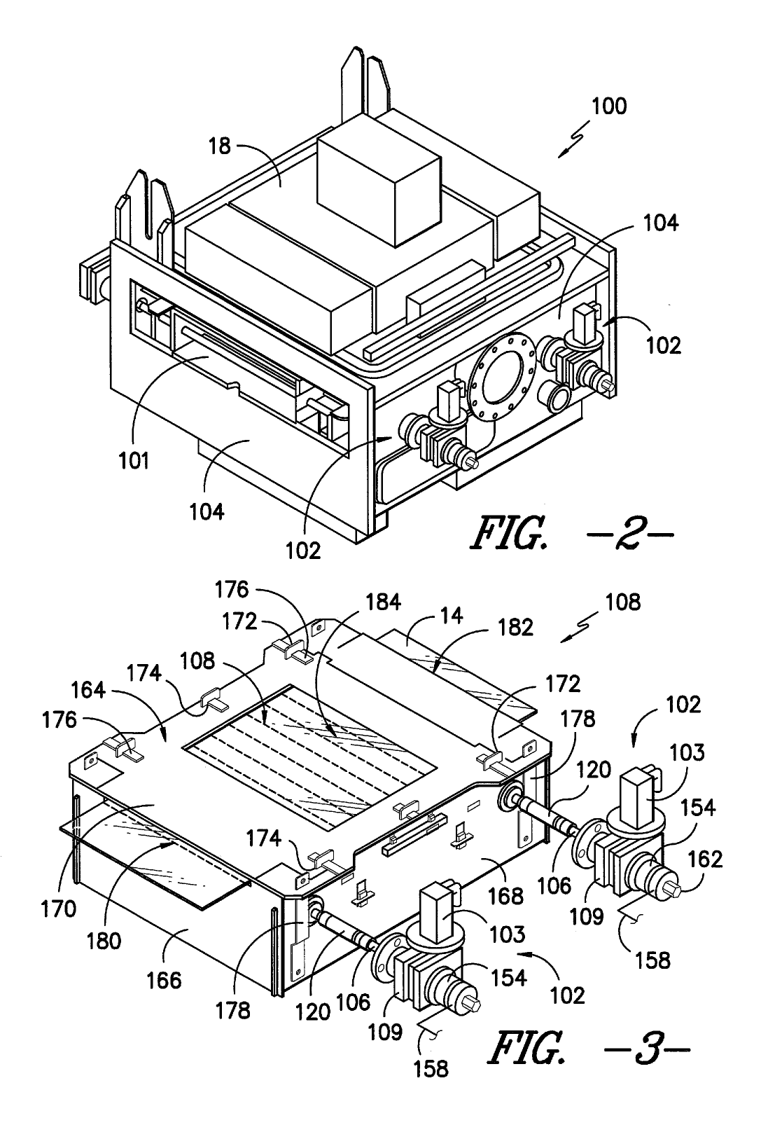

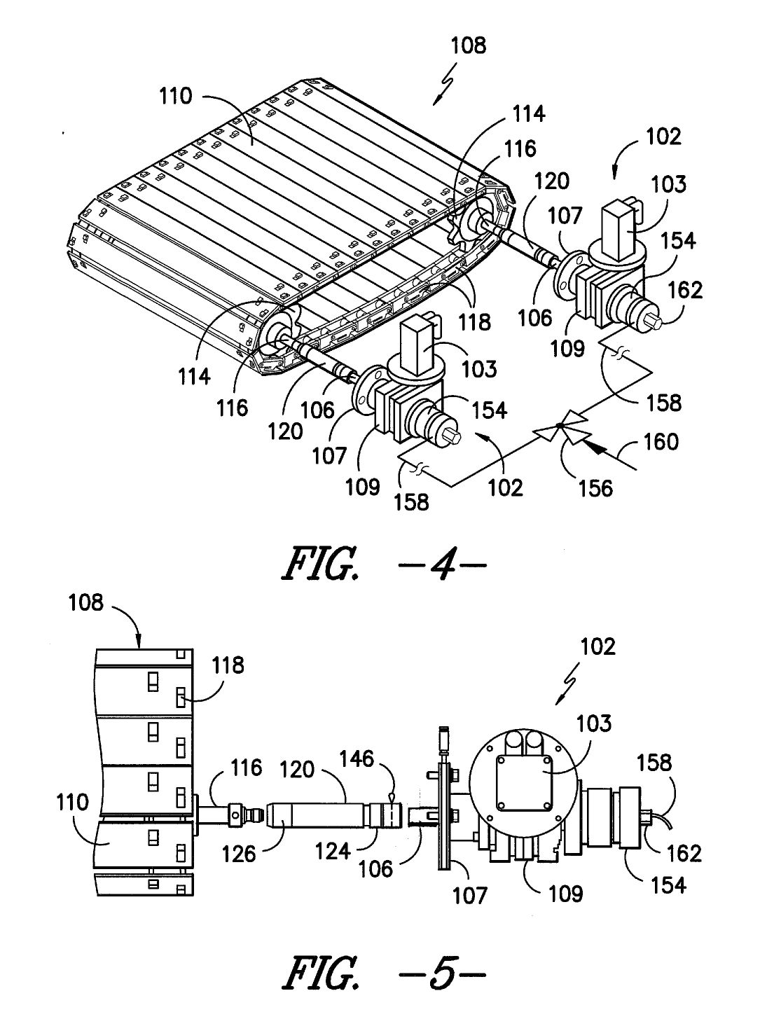

FIG. 2 depicts a module 100 that may be any one of the modules from the system 10 of FIG. 1. The module 100 includes exterior walls 104 and at least one drive unit 102 mounted on one of the exterior walls 104. The exterior walls 104 defined an entrance 101 for conveyance of substrates 14 through the module 100 by means of an internal conveyor 108 (FIGS. 3 and 4). In the illustrated embodiment, each module 100 includes two of the drive units 102 configured for driving the internal conveyor 108 in either direction, as explained more fully below.

The drive units 102 include a motor 103 configured on a drive unit housing 109. Any configuration of gearing or other transmission means may be contained within the housing 109 for conveying rotational torque to a drive shaft 106 associated with the drive unit 102. A flange 107 may be provided with the housing 109 for mounting the drive unit 102 onto a mounting surface or flange configured on the exterior wall 104 of the module 100.

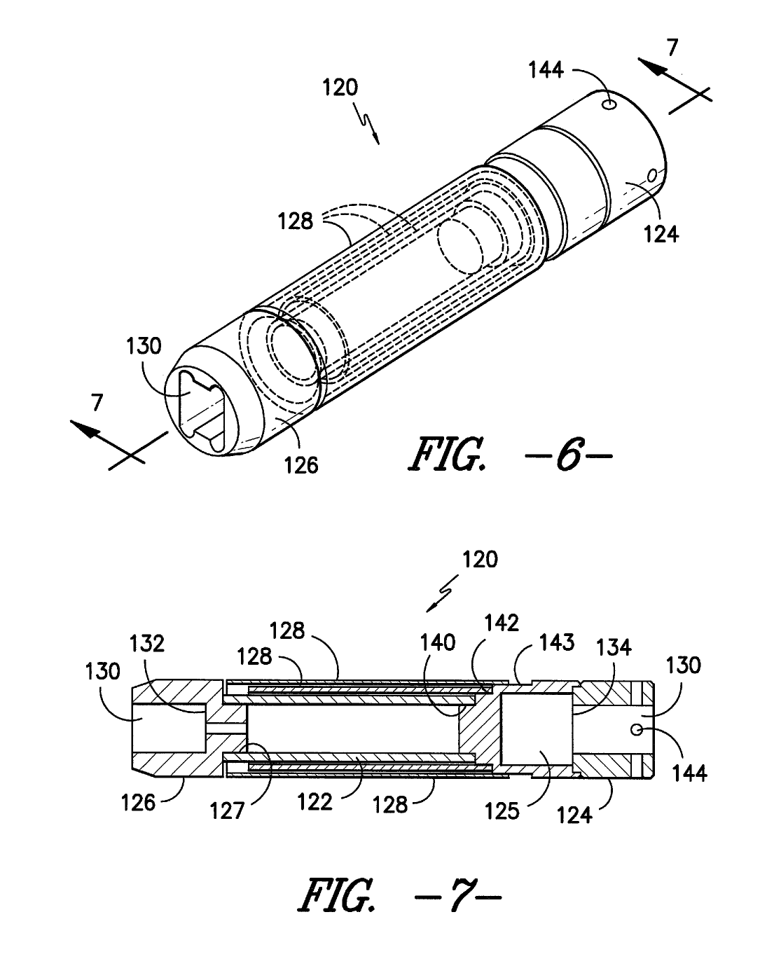

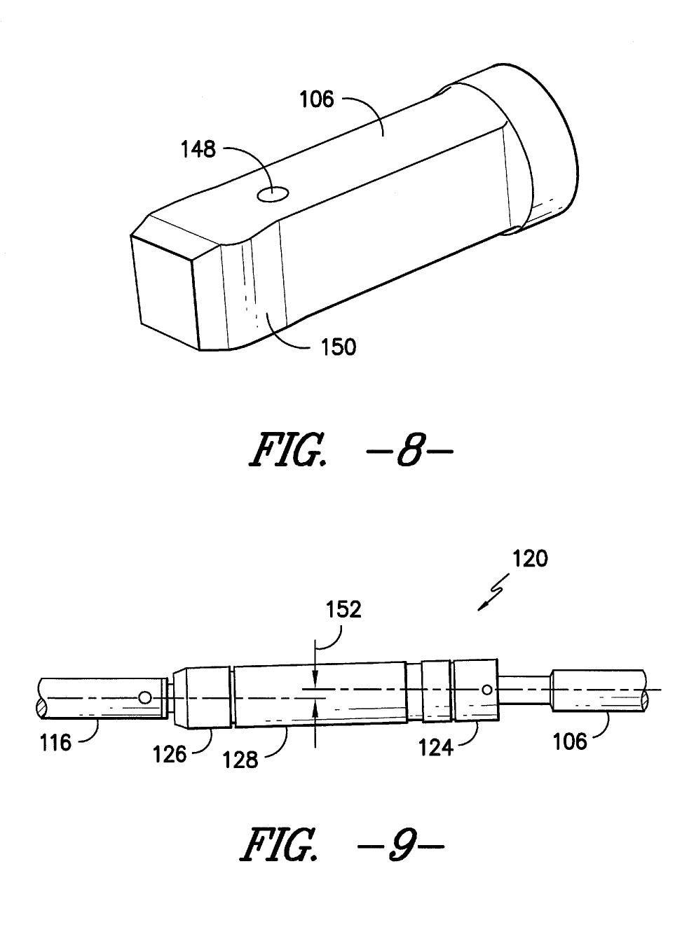

Referring to FIGS. 3 through 5, each of the drive units 102 is configured with a releasable coupling 120 operably configured between the driving member of the drive unit 102, i.e., the drive shaft 106, and a drive member of the conveyor 108, such as a sprocket shaft 116. The drive coupling 120 is releasably engaged between the respective shafts 106, 116 and includes a first end 124 rotationally engaged with the drive shaft 106 and a second end 126 rotationally engaged with the sprocket drive shaft 116. This rotational engagement may be by any suitable interface, including a keyed hub 130 (FIGS. 6 and 7) formed in the ends 124, 126 that engage with correspondingly shaped profiles on the respective drive shafts 106, 116. For example, the keyed hub 130 may be a hex-shaped recess that receives a hex-shaped end section of the drive shafts 106, 116, as depicted in FIG. 8. The shaft ends may be retained within the keyed hubs 130 (within the ends 124, 126) by any suitable releasable locking mechanism. In the illustrated embodiment, a cotter pin 146 (FIG. 5) is disposed through holes 144 in the first end 124 of the coupling 120 and holes 148 (FIG. 8) in the drive shaft 106 for releasably securing the components together. Other types of releasably locking mechanisms may also be used, such as a ball-detent, threaded sleeve, and so forth.

In the illustrated embodiment, the releasable coupling 102 is axially movable relative to the respective shafts 106, 116 upon releasing the locking mechanism (e.g., removing the cotter pin 146) for relatively simple removal of the coupling 102 from between the shafts. For example, referring to FIG. 7, the keyed hub 130 in the first end 124 of the coupling 120 includes an open end 134 that opens into chamber 125 that has a diameter at least as great as the widest dimension of the drive shaft 106. Upon removing the cotter pin 146 from the holes 144, the entire coupling 120 may be slid axially along the drive shaft 106, which will extend into the recess 125, until the opposite end 126 of the coupling disengages from the sprocket drive shaft 116. The keyed hub 130 in the second end 126 has a closed end 132 against which the end of the sprocket shaft 116 abuts. It should thus be appreciated that, with this particular embodiment, a releasable locking mechanism is not needed on both of the ends 124, 126. It should also be appreciated that the second end 126 may be configured with the chamber 125 such that the coupling 120 is slidable in the opposite direction.

Referring particularly to FIG. 7, the drive coupling 120 includes a torque member that transmits rotational torque from the drive shaft 106 to the sprocket drive shaft 116. In the illustrated embodiment, the torque member is defined by an innermost transmission tube 122 that is fixed between the ends 124, 126, for example mounted onto shoulders 140, 127 defined on each end. One or more concentric thermal shields 128 may surround the transmission tube 122 for dissipating and limiting heat transfer from the interior of the module 100 to the drive unit 102. These shields 128 extend axially around the transmission tube 122 and are attached to one of the ends 124, 126, but not to both ends. For example, in the illustrated embodiment, the two thermal shields 128 are mounted onto shoulders 142, 143 defined on the first end 124 and are unconnected to the second end 126. The shields 128 may be formed from any suitable heat-dissipating material.

In order to accommodate relative axial misalignment between the respective shafts 106, 116, a partially rounded engagement interface may be defined between the ends of the shafts and the respective keyed hubs 130. For example, referring to FIGS. 8 and 9, a rounded profile 150 is defined on opposite faces of the drive shaft 106. The same rounded profiles 150 would be defined on opposite faces of the sprocket drive shaft 116. These rounded profiles allow for a slight canting of the axis of the drive coupling 120 relative to the axis of the shafts. For example, as seen in FIG. 9, although the shafts 106 and 116 may be parallel, the axis of the shaft 106 is offset relative to the axis of the shaft 116 (as indicated by lines 152). The coupling 120, however, is capable of accommodating for this offset due to the partially rounded interface between the ends of the shafts 106, 116 within the keyed hubs 130. It should be appreciated that the rounded surfaces 150 may, alternatively, be defined within the keyed hubs 130.

The drive units 102 provide motive force to any manner of conveyor within the module 100. A particular embodiment of a conveyor 108 is illustrated in FIGS. 3 through 5 wherein a plurality of conveyor slats 110 form an endless conveyor that is driven around sprockets 114 by links 118 that attach the slats 118 together. Each of the sprockets 114 has a sprocket shaft 116 that may be configured as discussed above. At least one of the sprockets 114 is a drive sprocket (depending on the direction of rotation of the conveyor). The other sprocket 114 may be an idler sprocket. Typically, the upstream sprocket is the idler. The idler sprocket would not need a drive unit 102 if the conveyor 108 were configured for only unidirectional conveyance, as discussed more fully below.

Referring to FIGS. 3 and 4, a configuration of an internal conveyor 108 particularly suited for use in a vapor deposition module 60 (FIG. 1) is illustrated. The conveyor 108 may be modular in construction and configured for receipt within the module 60. The conveyor 108 may include a housing 164, as depicted in FIG. 3, which has been removed in the view of FIG. 4 for sake of clarity and explanation. The housing 164 defines an enclosed interior volume (at least around the sides and top) in which the slat conveyor 110 is driven in an endless loop having an upper leg that moves in a conveyance direction of the substrates 14 through the module 60, and a lower leg that moves in an opposite return direction. The housing 164 includes a top member 170 that defines an open “picture frame” deposition area 184 that aligns with a deposition head of the vapor deposition module 60. As can be seen in FIG. 3, the upper surface of the substrates 14 are exposed to the deposition process in the open deposition area 184. The top wall 170 defines an entry slot 180 and an exit slot 182 for the substrates 14 that are conveyed through the vapor deposition module 60. The clearance at these slots 180, 182 represents a potential source of leakage of the sublimated source material from the vapor deposition area. In this regard, it is desirable to keep the clearance between the upper surface of the substrates 14 at the entry and exit slots 180, 182 to a minimum.

Referring particularly to FIG. 3, the housing 164 includes end walls 166 and side walls 168. The end walls 166, side walls 168, and top wall 170 are connected to each other by a tab and slot arrangement wherein tabs 172 on one wall engage within slots 174 on another wall. Pins 176 engage through the tabs 172 to retain the components in a connected assembly. This embodiment is particularly useful in that mechanical fasteners, such as screws, bolts, and the like, are not necessary to assemble the housing 164. The components of the housing 164 simply slide together and are pinned in position relative to each other. Assembly and disassembly of the housing 164 for maintenance or other procedures is a relatively easy process in this regard.

The conveyor 108, particularly the housing 164, is configured for drop-in placement of the assembly 110 in the vapor deposition module 60. A plurality of braces 178 are attached to the side walls 168 and extend through slots in the top wall 170. These braces 178 define a plurality of lifting points for raising and lowering the conveyor assembly 108 into the vapor deposition module 60. When maintenance is required, the drive units 102 are disengaged from the conveyor assembly 108 by removing the drive couplings 120 as discussed above and the housing 164 is easily lifted from the module 60. A spare conveyor assembly 108 is readily dropped into the module 60 and engaged with the drive units 102 with the drive couplings 120. In this way, maintenance may be conducted on the removed assembly 108 while the processing line is returned to service. This keeps the vapor deposition line running in parallel with maintenance tasks.

The drive units 102 may be configured with a selectively actuatable clutch 154, as depicted in FIGS. 3 through 5. The clutch 154 may be, for example, a conventional pneumatic clutch supplied with actuating air via a pneumatic line 158. When actuated, the clutch 154 couples the motor and/or internal gears to the drive shaft 106. When deactivated, the clutch 154 uncouples to the drive shaft 106. With the embodiment wherein a drive unit 102 is configured with each sprocket of an endless conveyor 108, as in FIG. 3, a control mechanism may be provided to ensure that both drive units are not actuated at the same time. This mechanism may be, for example, a three-way valve 156 that is supplied with actuation air 160 from a suitable pressurized source. The valve 156 operates to ensure that the actuating air is directed to only one of the drive units 102, depending on the desired conveyance direction of the conveyor 108. Even if both drive units were reversible and drivable in the same direction (in either direction), as mentioned, it is generally preferred that the upstream sprocket 114 (of certain conveyor types) remain an idler sprocket.

The clutches 154 may also be torque limiting clutches that operate below a design maximum torque. If excess torque is produced, the clutches 154 slip, and may also trip an over-torque sensor. This safety feature prevents a jam from causing extensive damage to the conveyor 108.

When an enclosed module 100 is under high temperature and vacuum conditions, there is no easy means to evaluate the conditions of the conveyor 108 within the module. In this regard, it may be desired to include an externally accessible male driver configured on an end of the drive shaft 106, such as a hex head driver 162 depicted in FIGS. 3 through 5. This component 162 provides a simple diagnostic tool for a technician to check rotation of the drive shaft 106, jamming of the conveyor 108, premature wear of components, and so forth.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A module for a deposition system wherein a sublimated source material is deposited as a thin film on a substrate conveyed through said modules, said module comprising:
a drive unit mounted on an exterior wall of said module, said drive unit having a drive shaft that extends into said module;
a conveyor operably disposed within said module, said conveyor configured to be driven in a conveying path by said drive unit;
a releasable drive coupling configured between said drive unit and a drive member of said conveyor, said drive coupling comprising a first end that releasably engages said drive shaft and a second end that releasably engages said conveyor drive member; and,
said drive coupling further comprising a torque member and at least one thermal shield spaced concentrically around said torque member and extending axially between said first and second ends.

2. The module as in claim 1, wherein said torque member comprises an innermost torque transmission tube, and further comprising a plurality of said concentric thermal shields disposed around said torque transmission tube.

3. The module as in claim 1, wherein said first and second ends of said drive coupling comprise keyed hubs that engage with said drive shaft and a shaft extending from said conveyor drive member, respectively.

4. The module as in claim 3, wherein said drive coupling is axially movable along at least one of said drive shaft or conveyor drive member for disconnecting and removal of said drive coupling, and further comprising a releasable locking device for axially fixing said drive coupling relative to said drive shaft and said conveyor drive member.

5. The module as in claim 3, further comprising a partially rounded interface between said first end of said drive coupling and said drive shaft and between said second end of said drive coupling and said conveyor drive member, said rounded interfaces compensating for axial misalignment between said drive shaft and said conveyor drive member shaft.

6. The module as in claim 1, wherein said conveyor is configured to be driven in an endless loop path between opposite sprockets, at least one of said sprockets being a drive sprocket, said conveyor drive member comprising a sprocket shaft extending from said drive sprocket, said drive unit and drive coupling configured with said sprocket shaft, and further comprising a selectively actuatable clutch configured between said drive unit and said drive shaft.

7. The module as in claim 6, further comprising a respective said drive unit with associated said clutch and drive coupling configured with a shaft on said opposite sprocket, said clutches operably interfaced so that said clutches cannot be simultaneously engaged.

8. The module as in claim 7, wherein said clutches are pneumatic clutches, and further comprising a controllable three-way valve between an air source and said clutches wherein said valve permits actuating airflow to only one of said clutches at a time.

9. The module as in claim 7, wherein said pneumatic clutches are torque limiting clutches.

10. The module as in claim 6, wherein said drive shaft extends through said drive unit and said clutch and comprises an exposed keyed head for external rotation of said drive shaft.

11. The module as in claim 1, further comprising a conveyor housing disposed within said module, said conveyor and said sprockets configured within said conveyor housing, said conveyor housing removable from said module upon disconnecting said drive coupling from said drive shaft and said sprocket.

12. A deposition module wherein a sublimated source material is deposited as a thin film on a substrate conveyed through said module, said module comprising:
a conveyor operably disposed within said module to be driven in an endless loop path between opposite sprockets, at least one of said sprockets being a drive sprocket;
a drive unit mounted on an exterior wall of said module for each of said sprockets, said drive units having a drive shaft that extends into said module;
a releasable drive coupling configured between each said drive unit and said respective drive sprocket, said drive coupling comprising a first end that releasably engages said drive shaft and a second end that releasably engages said drive sprocket; and,
a selectively actuatable clutch configured between each said drive unit and respective said drive shaft, said clutches operably interfaced so that said clutches cannot be simultaneously engaged.

13. The deposition module as in claim 12, wherein said clutches are pneumatic clutches, and further comprising a controllable three-way valve between an air source and said clutches wherein said valve permits actuating airflow to only one of said clutches at a time.

14. The deposition module as in claim 12, wherein said pneumatic clutches are torque limiting clutches.

15. The deposition module as in claim 12, wherein said drive shaft extends through said drive unit and said clutch and comprises an exposed keyed head for external rotation of said drive shaft.

16. The deposition module as in claim 12, further comprising a conveyor housing disposed within said module, said conveyor and said sprockets configured within said conveyor housing, said conveyor housing removable from said module upon disconnecting said drive coupling from said drive shafts and said sprockets.

17. The deposition module as in claim 12, wherein said drive couplings comprise a torque member and at least one thermal shield spaced concentrically around said torque member and extending axially between said first and second ends.

18. The deposition module as in claim 17, wherein said torque member comprises an innermost torque transmission tube, and further comprising a plurality of said concentric thermal shields disposed around said torque transmission tube.

19. The deposition module as in claim 12, wherein said second end of said drive coupling engages a sprocket shaft extending from said sprocket, said drive coupling axially movable along at least one of said drive shaft or said sprocket shaft for disconnecting and removal of said drive coupling, and further comprising a releasable locking device for axially fixing said drive coupling relative to said drive shaft and said sprocket shaft.

20. The deposition module as in claim 19, further comprising a partially rounded interface between said first end of said drive coupling and said drive shaft and between said second end of said drive coupling and said sprocket shaft, said rounded interfaces compensating for axial misalignment between said drive shaft and said sprocket shaft.
